(19) United States
(12) Patent Application Publication
(10) Pub. No.: US 2007/0298606 A1
(43) Pub. Date: Dec. 27, 2007

(54) CHEMICAL-MECHANICAL POLISHING METHOD AND APPARATUS

(76) Inventors: Eric Neyret, Sassenage (FR); Cedric Angellier, Meylan (FR); Veronique Duquennoy-pont, Grenoble (FR)

Correspondence Address: WINSTON & STRAWN LLP;PATENT DEPARTMENT, 1700 K STREET, N.W., WASHINGTON, DC, 20006, US

(21) Appl. No.: 11/851,830

(22) Filed: Sep. 7, 2007

Related U.S. Application Data
(63) Continuation of application No. PCT/IB05/01461, filed on Apr. 22, 2005.

(51) Int. Cl. H01L 21/4763

(52) U.S. Cl. 438/633

(57) ABSTRACT

A method for manufacturing a semiconductor multilayer wafer by manufacturing an intermediate multilayer wafer having a polished layer from which a surface layer is obtained. The surface roughness is reduced by chemical-mechanical polishing (CMP) removal of part of the polish layer with the CMP monitored through reflectometry of light. The reflectometry produces a response that includes reference points associated with a known thickness of the polish layer and the CMP is stopped once a predetermined reference point has been reached. The method includes conducting a preliminary calibration of the CMP to define a preliminary thickness which corresponds to a preliminary value of thickness of the polish layer, wherein the preliminary thickness is defined by the total of a thickness of polish layer known associated with the predetermined reference point, and a thickness to be removed, and a thickness for the polish layer is provided which is substantially equal to the preliminary thickness.

### CROSS-REFERENCE TO RELATED APPLICATIONS

This application is a continuation of International application PCT/IB2005/001461 filed Apr. 22, 2005, the entire content of which is expressly incorporated herein by reference thereto.

### BACKGROUND

The present invention concerns the manufacturing of semiconductor wafers for applications such as microelectronics, optics, opto-electronics. More precisely, the invention concerns a method for manufacturing a semiconductor multilayer wafer having a thin surface layer, a support layer and a buried layer between the surface layer and the support layer. This method involves the manufacture of an intermediate multilayer wafer comprising the support and buried layers, and a polish layer from which the surface layer shall be obtained, the buried layer having a known thickness. It also includes a chemical-mechanical polishing (CMP) of the surface of the polish layer, in order to lower the surface roughness of the surface. The CMP is monitored through a reflectometry of light initially generated by a light source and then reflected by the intermediate multilayer wafer, with the reflectometry producing a substantially sinusoidal response of reflected light as a function of the thickness of the polish layer. This response comprises reference points such as peaks and bottoms, each reference point being associated to a respective known thickness of the polish layer. In this method, the CMP is stopped once a predetermined reference point has been reached. An associated apparatus also forms a part of this invention.

An “intermediate” wafer is defined as a wafer which is not in a finished state but has to undergo subsequent process steps—e.g., a CMP or other polishing step. The wafer can be of the SOI type, or of a different type. Such a wafer can in particular be obtained e.g. by a SMART-CUT® method, for which a general description can be found e.g. in “Silicon-On-Insulator technology: Materials to VLSI, 2^{nd} edition” by Jean-Pierre Colinge (Kluwer Academic Publishers)—in particular pp. 50-51.

The invention can advantageously be used for manufacturing multilayer wafers having a thin surface layer defining a “front” surface of the wafer, a support layer defining the “back” surface of the wafer, and a layer buried between the thin surface layer and the support layer. The thin surface layer of such wafers can have a thickness of 1 micron or even less—and in this text “thin” layer shall refer to a layer having such a thickness of 1 micron or less. The surface layer is generally referred to as the active layer of the wafer since active components shall be formed within this layer, both during or after the manufacturing of the wafer itself.

CMP is known for reducing the surface roughness of a wafer—and CMP can also be used in order to reduce the mean thickness of the surface layer of the wafer. However, CMP is also associated with some limitations and constraints. In particular, it is known that CMP can degrade the uniformity of the thickness of the wafer treated.

In the case of a multilayer for which it is desired to apply a CMP, it is thus known to define a desired duration for the CMP—for a given type of wafer to be polished, the desired duration is defined as a compromise so as to:
Be long enough to reduce the surface roughness in a desired manner,
Not be too long to significantly compromise the thickness uniformity over the wafer.
   Templates of desired CMP durations are thus known for selecting the desired duration of the CMP as a function of parameters such as the nature of the wafer to be polished. Once such desired duration has been selected, the CMP is carried out for the duration. However, in such case it is possible that once a wafer has undergone a CMP the thickness actually removed from the surface of the wafer differs—over the whole wafer surface, or only in some spots of the surface—from the thickness which was expected to be removed. This can be due e.g. to the state of the different parts of the CMP apparatus (e.g. the polishing pad of the apparatus can be more or less erased, . . . ).

In order to refine the control of a CMP operation, it is also known to carry out the following operations while the polish layer of an intermediate wafer is being polished by a CMP:
Illuminating the polish layer with a light of a given wavelength (such as a laser light),
retrieving with an appropriate sensor this light once it has been reflected by the polish layer with the underlying buried interface, and
to exploit the characteristics of the reflected light.
   The illumination of the wafer is performed through a transparent window of the polishing pad which covers the wafer. Such technique shall be referred to as “reflectometry” in the present text.

FIGS. 1a and 1b schematically illustrate a conventional CMP apparatus 10 with a polishing pad 100 covered by a slurry solution 101. The apparatus 10 further comprises a polishing head 110 which is in contact with the back surface (here represented facing upwards) of a wafer W. The wafer and the polishing head are bound together so that the wafer moves identically to the polishing head.

The front surface of the wafer—which corresponds to the exposed face of the polish layer—is in contact with the surface of the pad, but can be moved in a plane-over-plane movement over this surface as the wafer is moved by the polishing head. The pad is rotated as represented by arrow A100. This pad lies on a table 120 which is fixed. The polishing head 110 is also rotated, as represented by arrow A110. This rotation is transmitted to the wafer. The rotations of the pad and of the polishing head are carried out around different but parallel axis. The movement of the wafer relative to the pad which is generated by the combined rotations of the pad and the head, together with the presence of the slurry between the pad and the front surface of the wafer, allow the polishing of the front surface.

The table 120 further contains additional fixed elements under the pad. These elements include a light source 1200 such as a laser for generating a light having a controlled wavelength. This light is directed onto the front surface of the wafer, through a window 102 formed in the pad and transparent to the light. The window 102 is rotated with the pad and thus scans a region 1020 having the shape of a ring and intersecting the surface of the wafer. When the window 102 passes in front of the light source 1200, the light of the source thus hits the wafer and is reflected through the same window. The reflected light is sensed by a sensor 1201.

This reflected light is then analysed by processing means 1202 which are associated (i.e. which comprise or are connected to) memory means in which the reference points of a response curve and their respective associated reference thicknesses are stored (the “reference points” and “reference thickness” are defined further in this text). The processing means are adapted to compare the intensity of the reflected light to the reference points, and to provide an indication of the thickness of the polish layer which is being polished. This indication is used for stopping the polishing when a desired thickness is reached for the polish layer.

For a multilayer wafer (such as e.g. a SOI) which comprises a surface layer (e.g. in Si) and a buried layer (e.g. in oxide), the intensity of the reflected light is indeed known to be related to the thickness of the buried layer and to the thickness of the surface layer (which is here the polish layer). In other words, if the thickness of the buried layer of such wafer is known—which is generally the case since this thickness is often defined as a standard thickness (e.g. 1500 angströms)—the analysis of the reflected light gives access to the thickness of the surface layer.

To be more precise on the characteristics of the reflected light, we shall consider the case of a multilayer wafer with a buried layer having a known thickness, and a surface layer being polished. This layer corresponds to an intermediate surface layer since its thickness shall be modified by a CMP. It is thus also referred to as the “polish layer” in the present text. For such a wafer, it is known that the intensity of the reflected light shall vary periodically as a function of the thickness of the polish layer, along a sinusoidal curve (“response curve”).

This variation is illustrated in FIG. 2, which exhibits the intensity of reflected light as a function of the thickness of a polish layer which is the surface Si layer of a SOI. The curve of this figure exhibits regular peaks and bottoms. For a given multilayer wafer (characterized in first approach by its polish layer and its buried layer), and a given laser wavelength, the distance separating two successive peaks (or two successive bottoms, or a peak and the bottom which follows it . . . ) on such curve corresponds to a certain value of thickness for the polish layer. For such a curve, we will refer to the thickness corresponding to the distance between a bottom of the curve and its next peak as the “elementary thickness”.

The monitoring of the intensity of the reflected light, and of the evolution of such intensity, allows determining if this intensity is at a peak or at a bottom. These particular points of the curve of reflected light are indeed those which can be detected with the greatest accuracy. These peaks and bottoms will be referred to as “reference points” of the response curve of reflected light. Other types of reference points can possibly be used and more generally, the “reference points” are defined in this text as the points of a response curve which are known as being associated to a known value of thickness for the polish layer. Correspondingly, the “reference thickness” is defined as the thickness of the polish layer which is associated to a given reference point.

It is therefore possible to perform a CMP while at the same time monitoring the reflected light in real-time during the CMP, and stop the CMP once a determined number of peaks/bottoms of the reflected light have been detected. Such monitoring implies that several successive peaks/bottoms be successively detected during the CMP polishing of the polish layer. And it thus further implies that the accuracy desired for the thickness polished from the polish layer is not smaller than, or even in the order of, the elementary thickness considered. Such real-time monitoring can be an alternative to the mere use of a template for a desired CMP duration as mentioned above. Such monitoring can also be used in combination with such template. However, such monitoring is in itself not adapted to the monitoring of CMP when it is desired to remove only a very thin portion of a layer, with an accuracy in the order of (or even worse smaller than) the reference thickness used for the CMP.

For multilayer wafers having a thin polish layer, it can indeed be desired to polish the polish layer over a thickness of less than 450 angströms. The elementary thickness e.g., of a SOI comprising a buried oxide having a thickness of 1500 angströms, illuminated with a laser having a wavelength of 670 nm, is on the order of 450 angströms. In such case, the desired accuracy is in the order of the reference thickness and it is thus not possible to detect successive peaks/bottoms on a curve of reflected light for a wafer as mentioned above having a thin polish layer for which it is desired to polish only a thickness of less than 450 angtsröms.

In such a case, a monitoring could be carried out, but it is unlikely that the first reference point detected shall precisely correspond to the desired end of polishing. And it is likely that the detection of the second reference point would come too late (i.e. after the desired end of polishing has already been passed). And more generally, in such case the accuracy desired for the thickness polished is not significantly larger than the elementary thickness, and a monitoring as mentioned above is therefore not adapted. This corresponds to a limitation of the known methods for carrying out a CMP.

Thus, there is a need for avoiding these limitations, and a solution is now provided by the present invention.

### SUMMARY OF THE INVENTION

In one aspect, the invention relates to a method for manufacturing a semiconductor multilayer wafer having a thin surface layer, a support layer and a buried layer between the surface layer and the support layer. This method comprises:

manufacturing an intermediate multilayer wafer comprising the support and buried layers, and a polished layer from which the surface layer is to be obtained, wherein the buried layer has a known thickness,

chemical-mechanical polishing (CMP) of the polish layer to reduce surface roughness,

monitoring the CMP through a reflectometry of light initially generated by a light source and then reflected by the intermediate multilayer wafer, wherein the reflectometry produces a substantially sinusoidal response of reflected light as a function of the thickness of the polish layer, and the response includes reference points such as peaks and bottoms, with each reference point associated with a respective known thickness of the polish layer,

stopping the CMP once a predetermined reference point has been reached,

conducting a preliminary calibration of the CMP in order to define a preliminary thickness which corresponds to a preliminary value of thickness of the polish layer, wherein the preliminary thickness is defined by the total of a thickness of polish layer known associated with the predetermined reference point, and a thickness to be removed, and

providing a thickness for the polish layer which is substantially equal to the preliminary thickness before the CMP.

Preferred but non-limiting aspects of such a method are the following:

the preliminary thickness is comparable or lower than the elementary thickness defined by the response,

the buried layer is an oxide layer,

the buried layer has a thickness of 1500 angströms,

the multilayer wafer is a SOI,

the intermediate multilayer wafer is made using a layer transfer method, such as a SMART-CUT® method, with the creation of an embrittlement zone by implantation of species to define and transfer the surface layer,

the implantation parameters are defined in order to adapt the thickness of the polish layer before the CMP,

the implantation energy is defined in order to adapt the thickness of the polish layer before the CMP,

the intermediate multilayer wafer a sacrificial oxidation is carried out on the polish layer, and

the sacrificial oxidation are defined in order to adapt the thickness of the polish layer before the CMP.

In another aspect, the invention concerns a method for manufacturing a semiconductor multilayer wafer having a thin surface layer, a support layer and a buried layer between the surface layer and the support layer, which method comprises

manufacturing an intermediate multilayer wafer comprising the support and buried layers, and a polished layer from which the surface layer is to be obtained, wherein the buried layer has a known thickness,

chemical-mechanical polishing (CMP) of the polish layer to reduce surface roughness,

monitoring the CMP through a reflectometry of light initially generated by a light source and then reflected by the intermediate multilayer wafer, wherein the reflectometry produces a substantially sinusoidal response of reflected light as a function of the thickness of the polish layer, and the response includes reference points such as peaks and bottoms, with each reference point associated with a respective known thickness of the polish layer, and

stopping the CMP once a predetermined reference point has been reached,

wherein at least two light sources are used for the reflectometry, with each light source emitting a light having an individual wavelength, each individual light source generating a respective reflected light, each respective reflected light producing a respective substantially sinusoidal reflected response, and each light source has a different wavelength.

Preferred but non-limiting aspects of this method include those mentioned above as well as that the substantially sinusoidal response includes peaks and bottoms and that at least some intersecting points between two respective curves of two respective reflected responses provide reference points in addition to the peaks and bottoms.

The invention also relates to an apparatus for carrying out the methods described herein as well as for conducting CMP. This apparatus comprises:

polishing means for carrying out the CMP on a surface of a wafer,

illuminating means for illuminating the wafer,

sensor means for sensing the light reflected by the due to illumination and intensity of the reflected light, and

processing means for analyzing light intensity and for detecting reference points associated therewith,

wherein the illuminating means comprises at least two light sources, each light source emitting a respective illumination light onto the wafer surface, and the sensor means is adapted to sense the individual reflection of each illumination light.

Preferred but non-limiting aspects of such an apparatus are the following:

the illuminating means emit respective lights along different wavelengths,

the processing means are associated to memory means for storing the reference points, at least some intersecting points between the response curves obtained on the basis of the reflection of respective illumination lights being stored in the memory means, each such intersecting point being stored in association with the corresponding reference thickness of the polish layer associated to the intersecting point in order to form a reference point, and

the memory means comprise different registers, each register being associated to a particular type of wafer, each register comprising the reference points and their respective associated reference thicknesses for the particular type of wafer associated to the register.

### BRIEF DESCRIPTION OF THE DRAWINGS

Other aspects, goals and advantages of the invention shall be understood when reading the following description of preferred aspects of the invention, made in reference to the accompanying drawings in which:

FIGS. 1a and 1b schematically illustrate a conventional CMP apparatus, with FIG. 1a being a side view and FIG. 1b being a top view;

FIG. 2 exhibits the intensity of reflected light as a function of the thickness of a polish layer according to a prior art device; and

FIG. 3 is a graph showing a response curve for a CMP of a thin layer, with a desired thickness to be removed smaller than, or in the order of, the elementary thickness of the curve, in accordance with the teachings of the present invention.

### DETAILED DESCRIPTION OF THE PREFERRED EMBODIMENTS

It is specified that all comments made above in the introduction of this text (on the type of wafer concerned by the invention, and on the possible ways to manufacture the intermediate wafer) are applicable to all aspects of the invention.

The wafer can thus be a SOI, or another type of multilayer wafer, such as for instance Germanium on insulator or Silicon Germanium on Insulator wafers. The wafer may have been obtained e.g. by a SMART-CUT® layer transfer method. In such a case, the buried layer of the multilayer wafer can be an oxide, or a nitride layer or any other type of electrically insulating or conductive layer. It can have a typical thickness of e.g. 1500 angströms—this being presently a standard oxide thickness.

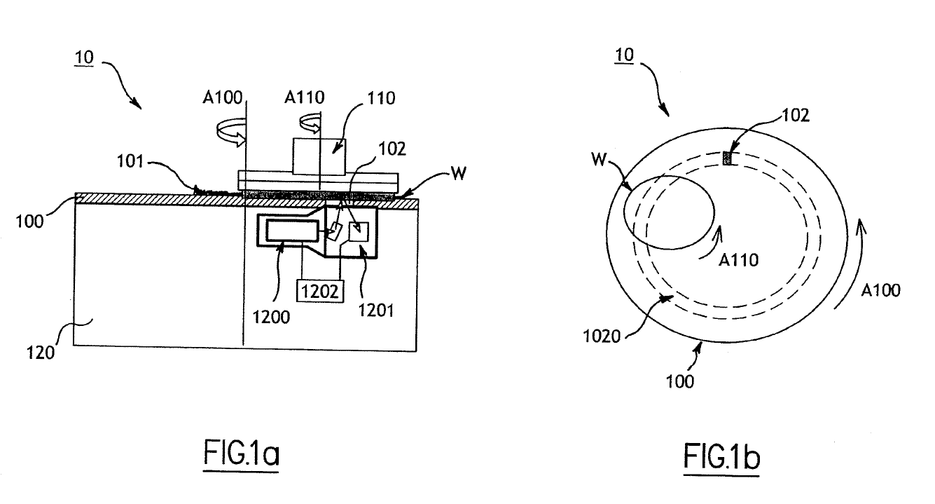

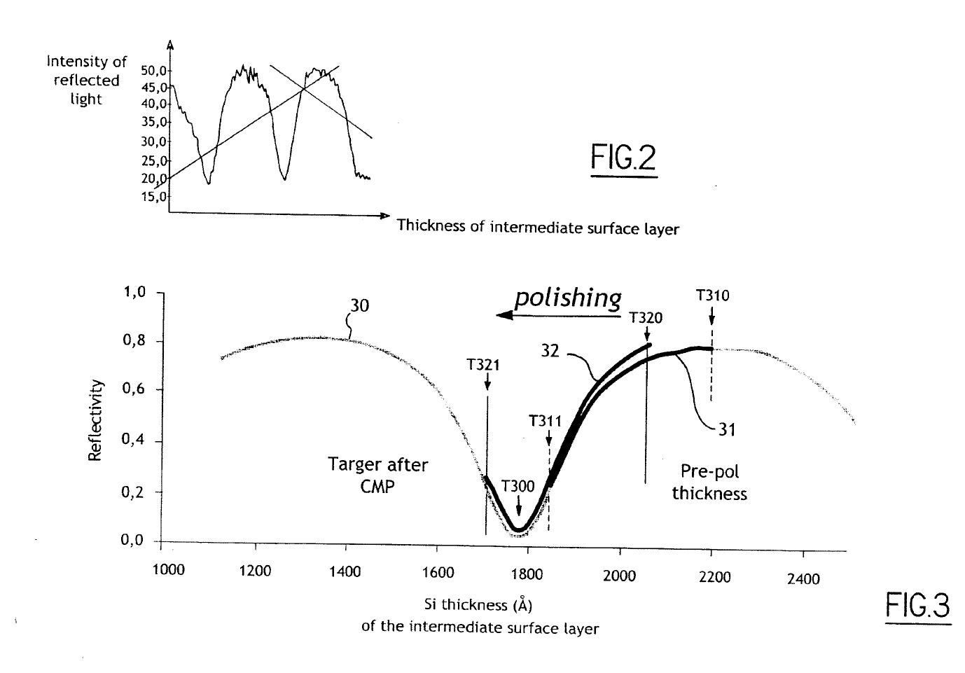

The invention is based on a reflectometry method and apparatus as described in the background with reference to FIGS. 1a, 1b and 2. The two aspects of the invention described herein are based on this background, and only the aspects which are specific to the invention shall be described. In particular, the invention implies monitoring the CMP by reflectometry, and stopping the CMP once a predetermined reference point has been detected.

Two main aspects of the invention shall be described further herein. These aspects can be carried out separately, or combined together. These two aspects are particularly well adapted for polishing by CMP a very small thickness of a thin layer—the thickness is typically comparable to, or even smaller than, the elementary thickness of the response curve considered for the monitoring by reflectometry.

Thin Layer—Comment

Before describing the invention, it is reminded that in the case where it is desired to obtain a thin film from a polish layer having undergone a CMP, the thickness to be removed from the polished layer has to be very low. But on the other hand, this thickness to be removed has to be large enough in order to efficiently reduce the surface roughness of the layer. In practice, the thickness to be removed can thus become a constraint, as its value is fixed by the above considerations. For the CMP of a polish layer in order to obtain a thin layer, this thickness can thus be considered as fixed. We will refer to this fixed thickness as the “thickness to be removed”.

First Aspect

According to a first aspect, the invention proposes a method carried out on an intermediate multilayer wafer, with a polish layer over a buried layer. A support layer can be below the buried layer. As mentioned above, the wafer can be a SOI.

A preliminary calibration of the CMP is carried out before the CMP itself, in order to define a preliminary thickness of the polish layer. It is recalled that the invention uses a monitoring by reflectometry and that the CMP shall be stopped by processing means such as the means 1202 described in reference to FIG. 1a. The preliminary thickness corresponds to a reference which shall be used for adapting the thickness of the polish layer before the CMP, and the reflectometry shall allow a finer definition of the thickness removed.

This “adaptation” shall be explained in more detail further herein. In other words, the preliminary calibration and the associated thickness adaptation (which shall be described further in this text) correspond to a “preliminary tuning” of the thickness before the CMP. And the subsequent “fine tuning” of the thickness of the polish layer is then made by reflectometry during the CMP. The thickness which shall actually be removed from the polish layer shall thus be determined by the end of the CMP, triggered by processing means associated to the reflectometry process.

The reflectometry implies the use of a response curve for a given wafer, and a given light source. The reflectometry apparatus comprises selecting means for selecting in the memory means a response curve corresponding to the wafer treated, and to the light source used (characterized in particular by its wavelength).

Preliminary Tuning—Principle of the Calibration

The preliminary calibration step of adapting the thickness of the polish layer (“preliminary tuning”) is carried out in a first step. For this first step, one has to know the reference curve (with its reference points and associated reference thicknesses) of the CMP which shall then be carried out on the polish layer.

As a preliminary tuning, the thickness of the polish layer of the intermediate wafer is adapted before the CMP, in order to be substantially equal to the addition of:
a thickness of polish layer known as being associated to one of the reference points of the response curve used for the reflectometry, and
the “removed thickness” (i.e. the thickness which shall actually be removed by CMP). The thickness of the polished layer is thus adapted to a “preliminary thickness” during this preliminary tuning. Preferred means for adapting the thickness of the polish layer shall be described further herein.

The purpose of this prior adaptation of the thickness before the CMP is to have the thickness of the polish layer substantially equal to a reference thickness once the CMP has been carried out in order to remove the preliminary thickness. Such prior adaptation allows to have the thickness of the polish layer correspond to a reference point towards the end of the CMP (the precise end of the CMP being defined by reflectometry), even if the thickness to be removed from the wafer is comparable to, or even smaller than, the elementary thickness of the response curve considered. More precisely, once the preliminary thickness has been defined as mentioned above the CMP begins and it is carried out under a monitoring by a reflectometry which monitors the intensity of reflected light.

Once a reference point is detected by such monitoring the CMP is stopped. More precisely, the processing means stop the CMP immediately after the reference point has been unambiguously detected. If the reference point is a peak or a bottom, such detection is characterized e.g. by the detection of a change of the sign of the first derivative of the intensity over time. And the unambiguous detection of such reference point implies that the CMP is still carried out for a very short time after passing the extremum corresponding to the reference point.

The principle of this aspect is schematically illustrated in FIG. 3. This figure comprises two response curves which represent two possible evolutions of the intensity of reflected light in a monitoring by reflectometry, as a function of time during a CMP (i.e. as a function of the thickness of the polish layer—expressed in angstroms). The two response curves 31, 32 correspond to substantially the same thickness removed from a polish layer. These curves 31, 32 are carried by a support curve 30 which is the reference curve stored in the memory means of the reflectometry apparatus. The reference curve of this particular example corresponds to a SOI and its elementary thickness is in the order of 450 angst\ddot{r}oms.

The two curves 31, 32 illustrate two respective CMPs for both of which the “thickness to be removed” is smaller than the elementary thickness of the support curve 30. The thickness to be removed (illustrated by the range of thickness covered by each of the two curves) is indeed in the order of 350 angströms. In such case, one has no real degree of freedom for selecting the thickness to be removed. Rather, the value of this thickness to be removed is a constraint and it has to be considered as a fixed value.

A first curve 31 illustrates a CMP carried out without a prior thickness adaptation according to the invention (no preliminary tuning). The CMP of this curve 31 has thus been started on an intermediate wafer having a polish layer whose thickness has not been adapted (pre-polishing thickness T310). Once the removed thickness has been removed, the thickness after CMP (T311) is in no way related to a reference point. And if the CMP is continued until the next reference point is reached too much thickness shall be removed from the polished layer. The references points are defined on curve 30 as the peaks and bottoms of this curve. It is reminded that other types of references points can possibly be defined.

The curve 32 illustrates a CMP carried out according to the first aspect of the invention. The thickness of the polish layer has been adapted before the CMP in order to have a value T320 which is substantially equal to the sum of the removed thickness (here about 350 angströms) and of a thickness corresponding to a reference point (here T300—which is slightly less than 1800 angströms). The CMP of curve 32 is stopped once the reference point corresponding to thickness T300 has been unambiguously detected by the reflectometry monitoring—which implies a final thickness T321 which is about 100 angströms thinner than T300. And the final thickness of the polish layer can be further adapted to satisfy final thickness requirement (that may differ from the thickness directly obtained after CMP) by performing a final sacrificial oxidation step.

Preliminary Tuning—Adaptation of the Thickness to a Preliminary Thickness

For adapting the thickness of the polish layer before the CMP, several methods can be contemplated. Two preferred methods are described below, but they are not limitative of the scope of the invention.

According to a first method, for manufacturing the intermediate multilayer wafer a SMART-CUT® method, with a creation of an embrittlement zone by implantation of species, is used. In such case the parameters of the implantation are defined in order to adapt the depth, in the implanted substrate, of the embrittlement zone created by implantation. This depth indeed determines the thickness of the polish layer, since this polish layer is obtained by detaching the implanted substrate at the embrittlement zone. Such control of the depth of the embrittlement zone is typically obtained by controlling the energy of the implantation.

According to a second method, during the manufacturing of the intermediate multilayer wafer a sacrificial oxidation is carried out on the polish layer. In such case the adaptation of the thickness of the polish layer can be obtained by defining the parameters of the sacrificial oxidation. This second method for adapting the thickness of the polish layer can be combined with the first method mentioned above (i.e. it is possible to use both the parameters of the implantation and the parameters of a subsequent sacrificial oxidation to adapt the thickness of the polish layer).

Second Aspect

A second aspect of the invention uses the principles and elements exposed above in reference to the reflectometry, and to FIGS. 1a and 2a. It furthermore brings additional elements. According to this aspect the invention uses an advanced reflectometry apparatus and method. More precisely, according to this second aspect:
at least two light sources are used in the reflectometry apparatus,
each light source emits onto the wafer a light having an individual wavelength, each individual light source generating a respective reflected light,
each respective reflected light produces a respective substantially sinusoidal reflected response (so that each respective reflected light produces a respective elementary reference curve), and
the wavelengths of the light sources are different.

Two or more light sources can be used in this manner. For each light source the reflected response is sensed, and monitored so as to produce an elementary reference curve. More precisely, in this case for a given wafer the elementary reference curve of each reflected response is memorized in the memory means of the reflectometry apparatus, and during the CMP the intensity (or reflectivity) of each of the respective reflected light is monitored and compared to the elementary reference curves memorized. Having different light sources associated to different wavelengths operating simultaneously allows to simultaneously monitor the CMP along different elementary reference curves having different periodicities. Indeed, the elementary reference curves associated to respective different illumination wavelengths shall have respective different periodicities. The monitoring of the CMP is thus carried out simultaneously along different elementary reference curves, memorized in the memory means of the apparatus.

Therefore, each elementary reference curve shall provide reference points, the reference points corresponding typically to the maxima and minima of intensity for each elementary reference curve. The reference points available are given in this case by the sum of the reference points of all elementary reference curves. This allows an increase in the total number of reference points over a given range of thickness—which is of course an advantage for the monitoring of the CMP. Moreover, these different elementary reference curves can be used to define additional reference points. It is indeed e.g. possible to define additional reference points as (all or part of) the intersecting points between two respective elementary reference curves.

The associated CMP apparatus shall include reflectometry means comprising:
Polishing means for carrying out a CMP on the polish layer of the intermediate multilayer wafer,
Illuminating means for illuminating the intermediate multilayer wafer,
Sensor means for sensing the light reflected by the intermediate multilayer wafer due to the illumination, and the intensity of the reflected light,
Processing means for analyzing the evolution of the light intensity and for detecting reference points associated thereto, but with the illuminating means comprising at least two light sources, each light source emitting a respective illumination light onto the wafer surface, and the sensor means are adapted to individually sense the reflection of each illumination light.

The processing means are associated to memory means for storing the reference points of all elementary reference curves, each reference point being stored in association with the corresponding reference thickness of the intermediate surface layer. And in all cases (first aspect and/or second aspect of the invention), the memory means of the apparatus used can comprise different registers, each register being associated to a particular type of wafer, each register comprising the reference points (coming from a single reference curve or from several elementary reference curves) and their respective associated reference thicknesses for the particular type of wafer associated to the register.

What is claimed is:

1. A method for manufacturing a semiconductor multilayer wafer having a thin surface layer, a support layer and a buried layer between the surface layer and the support layer, which comprises:
manufacturing an intermediate multilayer wafer comprising the support and buried layers, and a polished layer from which the surface layer is to be obtained, wherein the buried layer has a known thickness,
chemical-mechanical polishing (CMP) of the polish layer to reduce surface roughness,
monitoring the CMP through a reflectometry of light initially generated by a light source and then reflected by the intermediate multilayer wafer, wherein the reflectometry produces a substantially sinusoidal response of reflected light as a function of the thickness of the polish layer, and the response includes reference points such as peaks and bottoms, with each reference point associated with a respective known thickness of the polish layer,
stopping the CMP once a predetermined reference point has been reached,
conducting a preliminary calibration of the CMP in order to define a preliminary thickness which corresponds to a preliminary value of thickness of the polish layer, wherein the preliminary thickness is defined by the total of a thickness of polish layer known associated with the predetermined reference point, and a thickness to be removed, and
providing a thickness for the polish layer which is substantially equal to the preliminary thickness before the CMP.

2. The method of claim 1 wherein the preliminary thickness is comparable or lower than the elementary thickness defined by the response.

3. The method of claim 1 wherein the buried layer is an oxide layer.

4. The method of claim 1 wherein the buried layer has a thickness of 1500 angströms.

5. The method of claim 3 wherein the multilayer wafer is a SOI.

6. The method of claim 1 wherein the intermediate multilayer wafer is manufactured by a layer transfer method, with a creation of an embrittlement zone by implantation of species, which zone is later fractured to transfer the surface layer.

7. The method of claim 6 wherein the implantation is conducted with parameters defined to adapt the thickness of the polish layer before the CMP.

8. The method of claim 6 wherein the implantation is conducted with an energy that is defmed to adapt the thickness of the polish layer before the CMP.

9. The method of claim 1 wherein during the manufacturing of the intermediate multilayer wafer the polish layer is subjected to sacrificial oxidation.

10. The method of claim 9 wherein the sacrificial oxidation is conducted with parameters defined to adapt the thickness of the polish layer before the CMP.

11. A method for manufacturing a semiconductor multilayer wafer having a thin surface layer, a support layer and a buried layer between the surface layer and the support layer, which comprises:
manufacturing an intermediate multilayer wafer comprising the support and buried layers, and a polished layer from which the surface layer is to be obtained, wherein the buried layer has a known thickness,
chemical-mechanical polishing (CMP) of the polish layer to reduce surface roughness,
monitoring the CMP through a reflectometry of light initially generated by a light source and then reflected by the intermediate multilayer wafer, wherein the reflectometry produces a substantially sinusoidal response of reflected light as a function of the thickness of the polish layer, and the response includes reference points such as peaks and bottoms, with each reference point associated with a respective known thickness of the polish layer, and
stopping the CMP once a predetermined reference point has been reached,
wherein at least two light sources are used for the reflectometry, with each light source emitting a light having an individual wavelength, each individual light source generating a respective reflected light, each respective reflected light producing a respective substantially sinusoidal reflected response, and each light source has a different wavelength.

12. The method of claim 11 wherein the substantially sinusoidal response produces peaks and bottoms and at least some intersecting points between two respective curves of two respective reflected responses provide reference points in addition to the peaks and bottoms.

13. An apparatus for carrying out chemical-mechanical polishing (CMP) comprising:
polishing means for carrying out the CMP on a surface of a wafer,
illuminating means for illuminating the wafer,
sensor means for sensing the light reflected by the due to illumination and intensity of the reflected light, and
processing means for analyzing light intensity and for detecting reference points associated therewith,
wherein the illuminating means comprises at least two light sources, each light source emitting a respective illumination light onto the wafer surface, and the sensor means is adapted to sense the individual reflection of each illumination light.

14. The apparatus according to claim 13, wherein the light sources of the illuminating means emit respective lights along different wavelengths.

15. The apparatus according to claim 13, wherein the processing means is associated with memory means for storing the reference points, at least some intersecting points between the response curves obtained on the basis of the reflection of respective illumination lights being stored in the memory means, with each such intersecting point being stored in association with the corresponding reference thickness of a wafer layer associated with the intersecting point in order to form a reference point.

16. The apparatus according to claim 13, wherein the memory means comprises different registers, each register being associated to a particular type of wafer and comprising the reference points and their respective associated reference thicknesses for the particular type of wafer associated to the register.
